(19) United States
(12) Patent Application Publication
(10) Pub. No.: US 2008/0175290 A1
(43) Pub. Date: Jul. 24, 2008

(54) SEMICONDUCTOR DEVICE AND METHOD FOR FABRICATING THE SAME

(75) Inventors: Hirotada Satoyoshi, Yamanashi (JP); Satoshi Kajiyama, Yamanashi (JP); Syu Goto, Yamanashi (JP); Hiroyuki Sumitomo, Yamanashi (JP); Shigekazu Izumi, Yamanashi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EUDYNA DEVICES INC., Nakakoma-gun (JP)

(21) Appl. No.: 12/016,386

(22) Filed: Jan. 18, 2008

(30) Foreign Application Priority Data
Jan. 18, 2007 (JP) 2007-009619

(51) Int. Cl. H01S 5/30; H01L 21/304; H01L 33/00; H01L 29/04

(52) U.S. Cl. 372/44.011; 438/26; 438/463; 257/627; 257/E29.004; 257/E33.003; 257/E21.238

(57) ABSTRACT

A method for fabricating a semiconductor device includes dividing an off substrate so that a first edge face, the off substrate having an operation layer on a main surface of the off substrate, and cutting the off substrate to form a second edge face crossing the first edge face so that an entire surface of the second edge face is closer to a direction vertical to the main surface of the off substrate than a surface cleaved along with the second edge face.

### BACKGROUND OF THE INVENTION

1. Field of the Invention

The present invention generally relates to semiconductor devices and method for fabricating the same, and more particularly, to a semiconductor device having an off substrate and a method for fabricating the same.

2. Description of the Related Art

There is a semiconductor device having a layer epitaxially grown on an off layer. There is a case where a side edge face of a chip that forms semiconductor devices is a cleavage plane. Japanese Patent Application Publication No. 9-266347 discloses a technique that uses an off substrate in order to improve the concentration of p-type impurities and restrain natural superlattice. This technique produces an AlGaInP/GaAs based semiconductor laser that uses a GaAs substrate having the front (main) surface that is inclined from the (−100) plane to [0-11] or [01-1].

FIG. 1 is a perspective view of a laser diode (LD) using an off substrate. An operation layer 18 in which the carrier travels is provided on an n-type off substrate 10 (on a lower surface of the off substrate 10 in FIG. 1). The operation layer 18 is composed of an n-type second clad layer 12, an active layer 14 and a p-type first clad layer 16. A first electrode 20 is provided on the first clad layer 16, and a second electrode 22 is provided on a back surface of the off substrate 10 (on an upper surface thereof in FIG. 1). A waveguide path 24 for amplifying laser light is formed in the center of the active layer 14. The laser diode has first edge surfaces S1 and S2 and second edge surfaces S3a and S4a. Laser light is emitted from the first edge faces S1 and S2. The second edge faces S3a and S4a of the laser diode are provided so as to oppose each other in the width direction of the waveguide path 24. Further, the laser diode has surfaces S5 and S6. The main surface S5 of the laser diode is provided close to the operation layer 18 and is used to mount the laser diode on a package or the like. The main surface S5 is provided by the front surface of the off substrate 10. The surface S6 of the off substrate 10 is opposite to the main surface S5 and is defined by the back surface of the off substrate 10.

It is required that the first edge faces S1 and S2 of the laser diode are strictly parallel to each other in order to emit laser light from the edge faces S1 and S2 due to induced emission. Thus, the first edge faces S1 and S2 are required to be cleavage planes. For this purpose, a wafer is divided into substrates by scribing. When the off substrate 10 is an off substrate and scribing is used to divide the wafer into the individual laser diodes as described in the above-mentioned application, the second edge faces S3a and S4a are inevitably cleavage planes. Thus, an angle θ formed by the second edge face S3a and the main surface S5 is not perpendicular to the surface of the off substrate 10.

The following problems arise from a misalignment in which the second edge faces S3a and S4a are not perpendicular to the substrate. First, the second edge faces S3a and S4a are not perpendicular to the main surface S5 of the off substrate 10. Thus, there is a difficulty in mounting with the second edge faces S3a or S4a being used as a reference plane. More specifically, it is difficult to align the second edge faces S3a or S4a with a tool for mounting the semiconductor chip of the laser diode or a surface of a die bonder (with which the semiconductor chip is positioned). For example, the laser diode is required to have the laser emitting position strictly regulated. This requirement may be met by using image recognition. However, the image recognition increases the cost of mounting the semiconductor device.

Second, the semiconductor chip of the laser diode is liable to chipping at the time of holding the semiconductor chip by a pair of tweezers or die collets. It is therefore difficult to thin the semiconductor chip. Further, chipping increases dust.

### SUMMARY OF THE INVENTION

The present invention has been made in view of the above circumstances and provides a semiconductor device having a reduced cost of mounting and restrained chipping and a method for fabricating the same.

According to an aspect of the present invention, there is provided a method for fabricating a semiconductor device including: dividing an off substrate so that a first edge face, the off substrate having an operation layer on a main surface of the off substrate; and cutting the off substrate to form a second edge face crossing the first edge face so that an entire surface of the second edge face is closer to a direction vertical to the main surface of the off substrate than a surface cleaved along with the second edge face.

According to another aspect of the present invention, there is provided a method for fabricating a device including: providing a semiconductor device having an operation layer provided on an off substrate, a first edge face that is a cleavage plane and a second edge face crossing the first edge face, an entire surface of the second edge face being closer to a direction vertical to the main surface of the off substrate than a surface cleaved along with the second edge face; aligning the second edge face of the semiconductor device and a positioning portion of a mount portion; and subsequently securing the semiconductor device on the mount portion.

According to yet another aspect of the present invention, there is provided a semiconductor device including: an off substrate; an operation layer formed on a main surface the off substrate; a first edge face that is a cleavage plane of the off substrate; and a second edge face crossing the first edge face and an entire surface of the second edge face is closer to a direction vertical to the main surface of the off substrate than a surface cleaved along with the second edge face.

According to a further aspect of the present invention, there is provided a device including: a semiconductor device having an operation layer provided on an off substrate, a first edge face that is a cleavage plane and a second edge face crossing the first edge face, an entire face of the second edge face being closer to a direction vertical to the main surface of the off substrate than a surface cleaved along with the second edge face; and a mounting portion for securing the semiconductor device, the second edge face of the semiconductor device is aligned with a positioning portion of a mount portion.

### BRIEF DESCRIPTION OF THE DRAWINGS

FIG. 1 is a perspective view of a conventional laser diode;

FIG. 2 is a perspective view of a laser diode in accordance with a first embodiment;

FIG. 3 is a plan view of an off wafer employed in the first embodiment;

FIG. 4 shows crystal planes and directions;

FIGS. 5A through 5D are cross-sectional views of a wafer showing a method for fabricating the laser diode in accordance with the first embodiment;

FIG. 6 is a plan view showing the method for fabricating the laser diode in accordance with the first embodiment;

FIGS. 7A through 7C are plan views showing the method for fabricating the laser diode in accordance with the first embodiment; and

FIGS. 8A and 8B are perspective views of the laser diode mounted on a mount portion.

### DESCRIPTION OF THE PREFERRED EMBODIMENTS

A description will now be given of embodiments of the present invention with reference to the accompanying drawings.

### First Embodiment

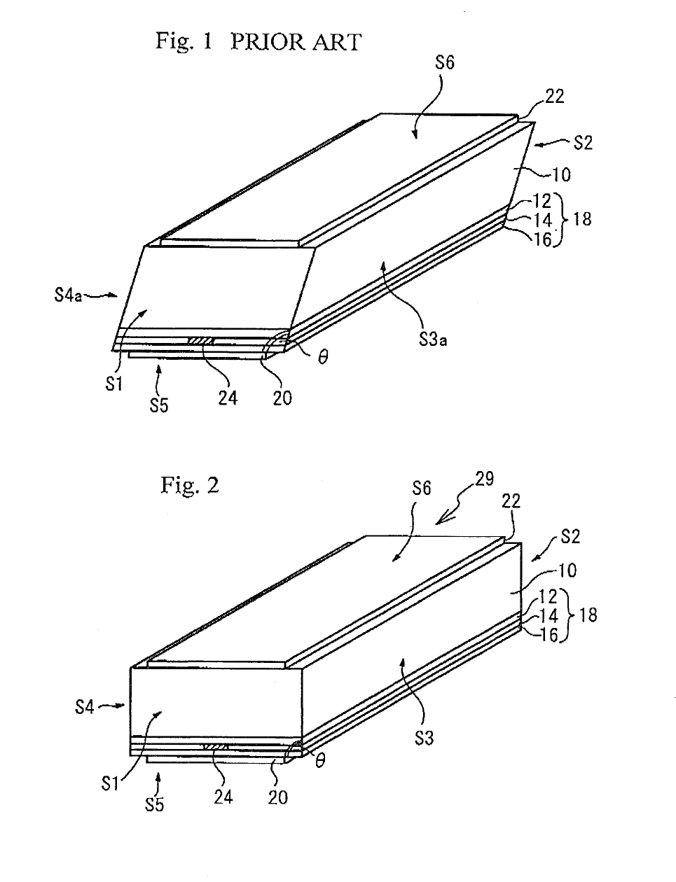

FIG. 2 is a perspective view of a laser diode chip (semiconductor chip) 29 in accordance with a first embodiment. In FIG. 2, parts that are similar to those shown in FIG. 1 are given identical reference numerals. The angles θ of the second edge faces S3 and S4 with respect to the main surface S5 of the off substrate 10 is 90 degrees. The other structure of the laser diode chip 29 is the same as that of the laser diode chip shown in FIG. 1.

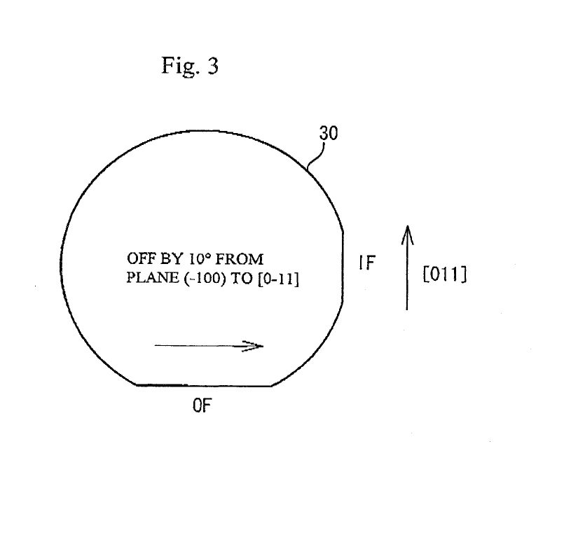

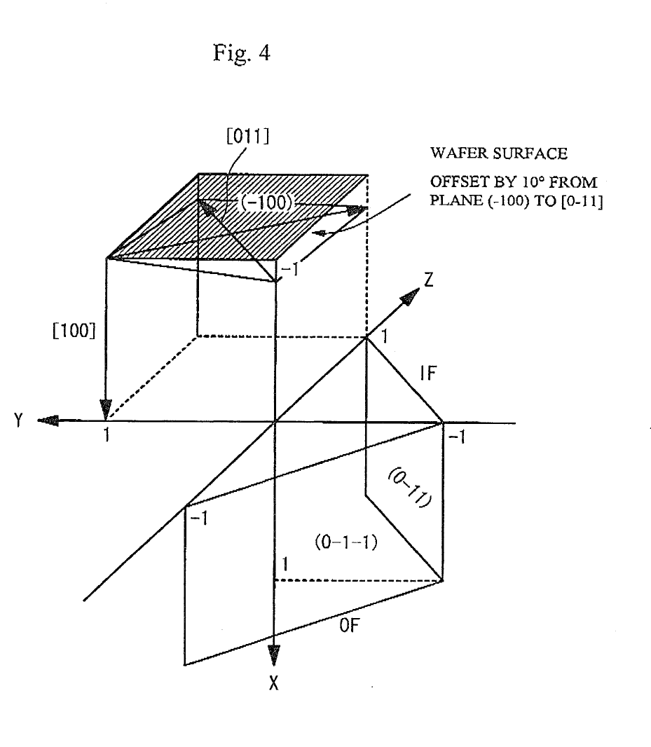

FIG. 3 shows a GaAs (gallium arsenide) wafer used for forming laser diode chips of the first embodiment. The main surface (front surface) of a GaAs wafer 30 is 10° off from the (−100) plane to [0-11]. FIG. 4 shows the crystal planes and crystal directions of GaAs. The plane that is 10° off to [0-11] with respect to the (−100) plane is the front wafer surface. Turning to FIG. 3 again, the horizontal direction of a major orientation flat (OF) of the wafer is also 10° off. The horizontal direction of an index flat (minor orientation flat, IF) is [011].

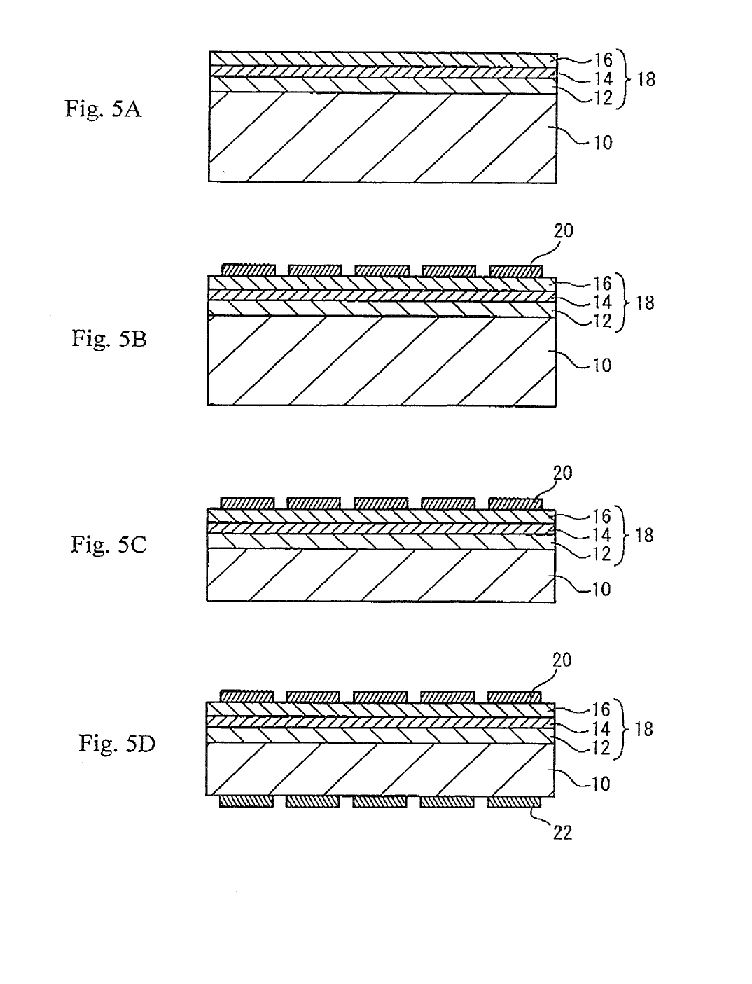

A description will now be given, with reference to FIGS. 5A through 7C, of a method for fabricating the semiconductor device in accordance with the first embodiment. As shown in FIG. 5A, the operation layer 18 composed of the second clad layer 12 of n type, the active layer 14 and the first clad layer 16 of p type is grown on the n-type GaAs substrate 10 doped with Si (silicon) by MOCVD (Metal Organic Chemical Vapor Deposition) in that order. The second clad layer 12 is made of AlGaInP (aluminum gallium indium phosphate). The active layer 14 is formed by MQW (multi-quantum well) of InGaP/AlGaInP. The first clad layer 16 is made of AlGaInP doped with Zn (zinc).

As shown in FIG. 5B, the first electrodes 20 are formed on the main surface of the off substrate 10 by evaporation. As shown in FIG. 5C, the back surface of the off substrate 10 is grinded for thinning. As shown in FIG. 5D, the second electrodes 22 are formed on the back surface of the off substrate 10 by evaporation so as to be aligned with the first electrode 20.

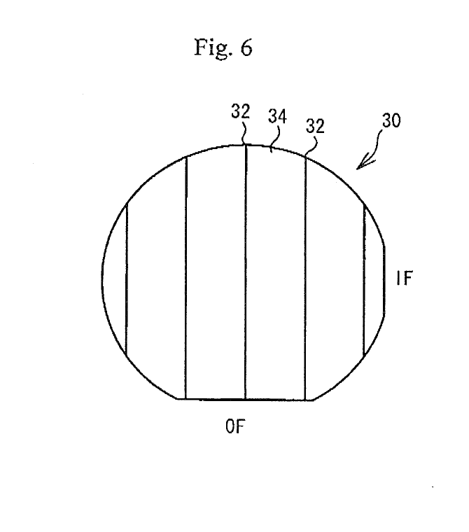

Referring to FIG. 6, the wafer 30 on which laser diodes are formed as mentioned above is divided into parts in the IF direction by laser dividing or dicing. This dividing of the wafer 30 results in strip pieces 34 along divided planes 32 extending in the IF direction.

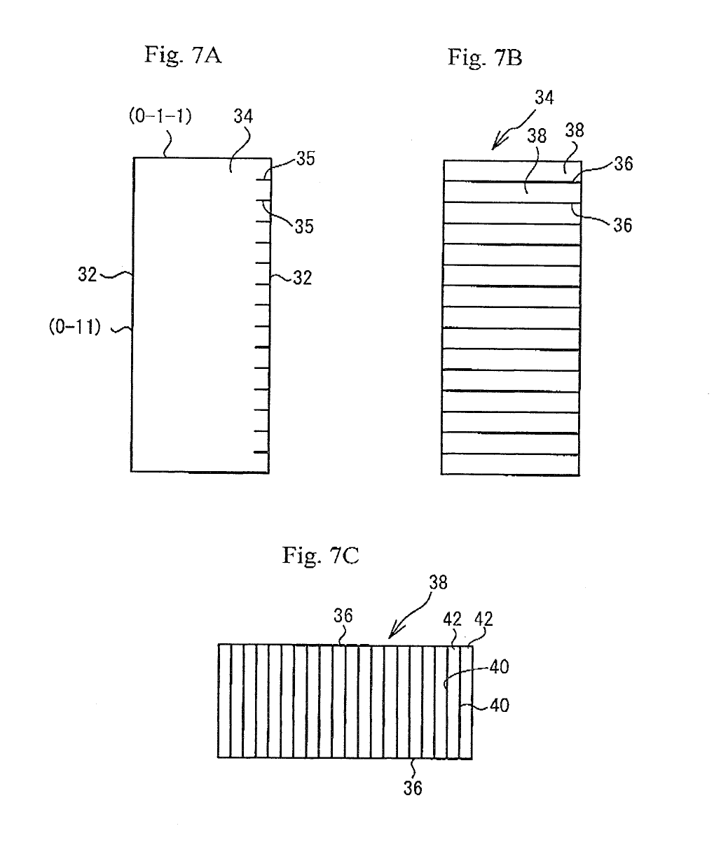

Referring to FIG. 7A, scribe lines 35 are formed on the divided plane 32 of each strip piece 34 by scribing. The scribe lines 35 are pushed upwards or downwards, so that the strip piece 34 is cleaved along cleavage planes 36 (0-1-1) (first cleavage planes). Thus, strip pieces 38 divided along cleavage planes 36 are obtained. The cleavage planes 36 correspond to the first edge faces S1 and S2 of the laser diode chip 29 shown in FIG. 2.

As shown in FIG. 7C, the strip pieces 38 are divided into strip pieces 42 along divided planes 40 in the direction perpendicular to the cleavage planes 36 by laser dividing or dicing. The divided planes 40 correspond to the second edge faces S3 and S4 of the laser diode shown in FIG. 2. Each of the strip pieces 42 corresponds to the laser diode chip shown in FIG. 2. The length of the laser diode in the longitudinal direction (the distance between the first edge faces S1 and S2 shown in FIG. 2) ranges from, for example, 200 μm to 2200 μm, and the width thereof (the distance between the second edge faces S3 and S4 in FIG. 2) ranges from, for example, 150 μm to 250 μm.

The laser dividing employed in FIGS. 6 and 7C may use a laser apparatus handling pulse laser and may be carried out under exemplary conditions having a pulse width of 120 fSeconds, a center wavelength of 800 nm, a pulse energy of 0.01 mJ/pulse, a lens focal distance of 100 mm, and a number of laser shots of 20. Dicing may be used instead of laser dividing. Dicing may be carried out under exemplary conditions having a blade width of 0.01 mm, a number of blade revolutions of 30000 rpm, a flow rate of coolant of 11 liters per minute and a cutting speed of 10 mm per second.

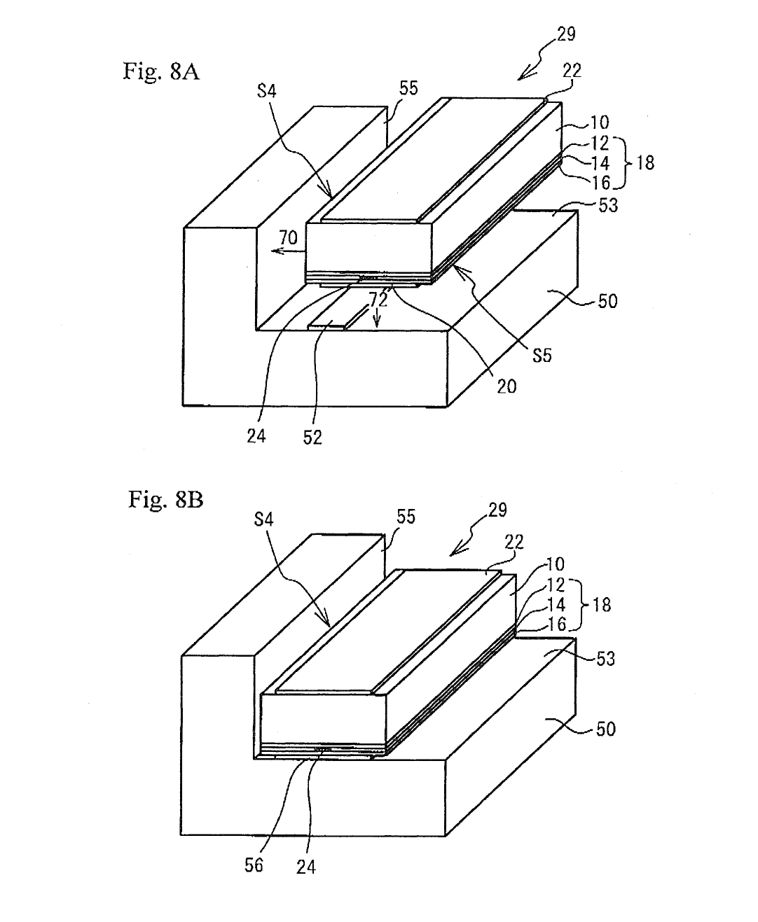

FIGS. 8A and 8B are respectively perspective views of the laser diode chip 29 (semiconductor element) shown in FIG. 2 that is mounted on a mount portion. As shown in FIG. 8A, a sub carrier 50, which may, for example, a ceramic sub carrier, has an L shape, and has a surface 53 on which the laser diode chip 29 is mounted, and a positioning surface (positioning portion) 55. A brazing member 52 made of AuSn or solder is provided on the surface 53. The second edge face S4 of the laser diode chip 29 is brought into contact with the positioning surface 55 of the sub carrier 50 as indicated by an arrow 70, so that the laser diode chip 29 can be positioned horizontally. Then, the front surface S5 of the laser diode chip 29 is brought into contact with the surface 53 as indicated by an arrow 72.

As shown in FIG. 8B the first electrode 20 and the brazing member 52 are reacted so that a joint portion 56 can be formed. Then, the sub carrier 50 may be housed in a package or mounted on a substrate.

In the first embodiment, as shown in FIG. 7B, the strip piece 34 (that is, the off substrate 10) is divided so that the first edge faces S1 and S2 of the laser diode chip 29 are cleavage planes (first cleavage planes). Further, as shown in FIG. 7C, the strip piece 38 (that is, the off substrate 10) is divided so that the second edge faces S3 and S4 of the laser diode orthogonal to the first edge faces S and S2 thereof are perpendicular to the front surface S5 of the off substrate 10. The first edge faces S1 and S2 from which laser light is emitted are the cleavage planes, and the second edge faces S3 and S4 orthogonal to the first edge faces S1 and S2 are perpendicular to the front surface S5 of the off substrate 10.

With the above structure, it is possible to position the laser diode chip 29 with reference to the second edge faces S3 or S4. That is, as shown in FIG. 8A, the second plane S4 and the positioning surface 55 of the sub carrier 50 are positioned. After that, the laser diode chip 29 (semiconductor element) is mounted on the sub carrier 50 (mount portion), as shown in FIG. 8B. The laser diode chip 29 can be positioned horizontally by bring the second edge face S4 of the laser diode chip 29 into contact with the positioning surface 55 of the sub carrier 50. Thus, the mounting procedure for the chip 29 does not need image recognition and reduces the production cost. The positioning surface 55 of the sub carrier 50 may be a plane defined by a die bonder, tool or package. The mount portion on which the laser diode chip 29 is mounted may be a package such as a stem or a substrate.

It is further possible to restrain chipping caused at the time of holding the laser diode chip 29 by a pair of tweezers or die collets. Thus, the laser diode chip 29 can be thinned. In addition, dust caused by chipping can be restrained. The entire second edge faces S3 and S4 crossing the first edge faces S1 and S2 are closer to the direction vertical to the main surface S5 of the off substrate 10 than another cleavage plane existing at a cross of the first edge faces S1 and S2 of the off substrate 10 (said another cleavage plane is the second edge faces S3a and S4a of the off substrate 10 shown in FIG. 1: second cleavage planes). In other words, the entire surfaces of the second edge faces S3 and S4 are closer to the direction vertical to the main surface of the off substrate 10 than the edge faces S3a and S4a cleaved along with the second edge faces S3 and S4. It is thus possible to easily position the laser diode chip 29 by using the positioning surface 55 of the sub carrier 50, as compared to the laser diode chip shown in FIG. 1. In order to facilitate positioning of the laser diode chip 29, the second edge faces S3 and S4 of the off substrate 10 are inclined within an angle equal to or smaller than 5′ with respect to the front surface S5 of the off substrate 10. Thus, the first embodiment is particularly advantageous to a case where the off angle of the off substrate 10 is equal to or greater than 5°.

The second edge faces S3 and S4 and the first edge faces S1 and S2 may be formed by a method other than the methods described in connection with the first embodiment. Preferably, the cleavage planes 36 are formed by scribing. It is thus possible to easily form the first and second edge faces S1 and S2 that are the cleavage planes. As shown in FIG. 7A, the divided planes 40 are preferably formed by laser dividing or dicing. Thus, the divided planes 40 are not cleavage planes, so that the second edge faces S3 and S4 of the off substrate 10 can easily be made vertical to the front surface S5 thereof. The second edge faces S3 and S4 and the first edge faces S1 and S2 may be formed by another sequence, which may be reverse to the above-mentioned sequence.

As shown in FIG. 5C, the first electrodes 20 are formed on the front side of the off substrate 10. As shown in FIG. 5D, the second electrodes 22 are formed on the backside of the off substrate 10 so as to be aligned with the first electrodes 20. The second edge faces S3 and S4 are vertical to the front surface S5 of the off substrate 10, so that the first electrodes 20 and the second electrodes 22 can be aligned with each other. Conventionally, as shown in FIG. 1, the first electrodes 20 and the second electrodes 22 respectively formed on the second edge faces S3 and S4 are offset. If the conventional off substrate 10 is divided in the same manner as that of the first embodiment in which the second edge faces S3 and S4 are divided in the direction vertical to the surfaces S5 and S6, the first electrode 20 and the second electrode 22 will be divided. In contrast, according to the first embodiment, the first electrode 20 and the second electrode 22 are aligned with each other, so that the second edge faces S3 and S4 of the off substrate 10 can be formed without diving the first electrode 20 and the second electrode 22.

The first edge faces S1 and S2 of the off substrate 10 are vertical to the front surface S5 and the second edge faces S3 and S4 of the off substrate 10. Thus, induced emission of laser light takes place within the waveguide path 24 between the edge faces S1 and S2.

The off substrate 10 is not limited to the GaAs substrate. However, preferably, the off substrate 10 is made of InP (indium phosphate) or GaAs in order to form cleavage planes.

The first edge faces S1 and S2 of the off substrate 10 are essentially planes cleaved (cleavage planes), and are not limited to the (011) or (0-1-1) planes. The surface of the off substrate 10 is not limited to the plane that is off from (−100) or (100) to [0-11] but may be preferably a plane that is off to the plane vertical to the first edge face S1 or S2 ([0-11] or [01-1] in the first embodiment). It is thus possible to form the first edge faces S1 and S2 vertical to the front surface S5 and the second edge faces S3 and S4 of the off substrate 10.

The semiconductor device of the present invention is the exemplary laser diode in the first embodiment. The present invention includes other types of semiconductor devices having the off substrate 10 and cleavage planes. For example, the present invention includes an LED (Light Emitting Diode), a VCSEL (Vertical Cavity Surface Emitting Laser), a light-receiving element and an FET (Field Effect Transistor). In these semiconductor devices, the first planes are divided along cleavage planes, so that the semiconductor chip can be easily divided. Further, the second edge s are close to the direction vertical to the cleavage plane, so that the chip can be positioned easily. The operation layers of the above semiconductor devices are layers in which the electrons or holes travel.

The present invention is not limited to the specifically described embodiments, but may include other embodiments and variations without departing from the scope of the present invention.

The present application is based on Japanese Patent Application No. 2007-009619 filed Jan. 18, 2007, the entire disclosure of which is hereby incorporated by reference.

What is claimed is:

1. A method for fabricating a semiconductor device comprising:
dividing an off substrate so that a first edge face, the off substrate having an operation layer on a main surface of the off substrate; and
cutting the off substrate to form a second edge face crossing the first edge face so that an entire surface of the second edge face is closer to a direction vertical to the main surface of the off substrate than a surface cleaved along with the second edge face.

2. The method as claimed in claim 1, wherein dividing the off substrate employs laser dividing or dicing.

3. A method for fabricating a device comprising:
providing a semiconductor device having an operation layer provided on an off substrate, a first edge face that is a cleavage plane and a second edge face crossing the first edge face, an entire surface of the second edge face being closer to a direction vertical to the main surface of the off substrate than a surface cleaved along with the second edge face;
aligning the second edge face of the semiconductor device and a positioning portion of a mount portion; and
subsequently securing the semiconductor device on the mount portion.

4. The method as claimed in claim 1, wherein the off substrate is made of InP or GaAs.

5. The method as claimed in claim 1, wherein the semiconductor device is a laser diode, and laser light is emitted from the first edge face.

6. The method as claimed in claim 1, further comprising:
forming first electrodes on the main surface of the off substrate; and
forming second electrodes on a surface of the off substrate opposite to the main surface so as to be aligned with the first electrodes.

7. The method as claimed in claim 1, wherein the first edge face is vertical to the main surface and the second edge face of the off substrate.

8. The method as claimed in claim 1, wherein the off substrate is off from (−100) to [0-11].

9. The method as claimed in claim 1, wherein the off substrate has an off angle equal to or greater than 5 degrees.

10. A semiconductor device comprising:
an off substrate;
an operation layer formed on a main surface the off substrate;
a first edge face that is a cleavage plane of the off substrate; and
a second edge face crossing the first edge face and an entire surface of the second edge face is closer to a direction vertical to the main surface of the off substrate than a surface cleaved along with the second edge face.

11. A device comprising:
a semiconductor device having an operation layer provided on an off substrate, a first edge face that is a cleavage plane and a second edge face crossing the first edge face, an entire face of the second edge face being closer to a direction vertical to the main surface of the off substrate than a surface cleaved along with the second edge face; and
a mounting portion for securing the semiconductor device, the second edge face of the semiconductor device is aligned with a positioning portion of a mount portion.

12. The semiconductor device as claimed in claim 10, wherein the off substrate is made of InP or GaAs.

13. The semiconductor device as claimed in claim 10, wherein the semiconductor device is a laser diode, and laser light is emitted from the first surface.

14. The semiconductor device as claimed in claim 10, wherein the off substrate is off from (−100) to [0-11].

15. The semiconductor device as claimed in claim 10, wherein the off substrate has an off angle equal to or greater than 5 degrees.
